(19) United States
(12) Patent Application Publication
(10) Pub. No.: US 2025/0364050 A1
(43) Pub. Date: Nov. 27, 2025

(54) MEMORY DEVICES AND OPERATION METHODS THEREOF, AND MEMORY SYSTEMS

(71) Applicant: Yangtze Memory Technologies Co., Ltd., Wuhan (CN)

(72) Inventors: Yang Zhang, Wuhan (CN); Masao Kuriyama, Wuhan (CN)

(21) Appl. No.: 18/912,223

(22) Filed: Oct. 10, 2024

(30) Foreign Application Priority Data
May 21, 2024 (CN) 202410642395.9

(51) Int. Cl. G11C 16/10; G11C 16/04; G11C 16/08; G11C 16/30

(52) U.S. Cl. CPC G11C 16/10; G11C 16/0483; G11C 16/08; G11C 16/30

(57) ABSTRACT

Examples of the present disclosure provide a memory device and an operation method thereof, and a memory system. The memory device includes: a memory cell array; and a peripheral circuit coupled to the memory cell array and configured to: determine a target voltage difference according to a target program voltage; determine a channel boost voltage according to a difference between the target program voltage and the target voltage difference; apply the channel boost voltage to a selected word line during a channel boost stage; and apply the target program voltage to the selected word line during a program pulse stage.

### CROSS-REFERENCE TO RELATED APPLICATIONS

This application claims priority to and the benefit of Chinese Patent Application 202410642395.9, filed on May 21, 2024, which is hereby incorporated by reference in its entirety.

### TECHNICAL FIELD

Examples of the present disclosure relate to the technical field of semiconductors, and particularly to memory devices and operation methods thereof, and memory systems.

### BACKGROUND

A memory device is a storage apparatus configured to store information in the modern information technology. As a typical non-volatile semiconductor memory, the NAND (Not-And) flash memory has become a mainstream product in the storage market due to its relatively high storage density, controllable production costs, appropriate program and erase speeds, and retention property.

### BRIEF DESCRIPTION OF THE DRAWINGS

FIG. 1 is a schematic diagram of an example system having a memory system according to an example of the present disclosure;

FIG. 2A is a schematic diagram of an example memory card having a memory system according to an example of the present disclosure;

FIG. 2B is a schematic diagram of an example solid state drive having a memory system according to an example of the present disclosure;

FIG. 3A is a schematic diagram of a memory cell distribution of a three-dimensional NAND memory according to an example of the present disclosure;

FIG. 3B is a schematic diagram of an example memory device comprising a peripheral circuit according to an example of the present disclosure;

FIG. 4 is a schematic cross-sectional view of a memory array comprising a NAND memory string according to an example of the present disclosure;

FIG. 5 is a schematic diagram of an example memory device comprising a memory cell array and a peripheral circuit according to an example of the present disclosure;

FIG. 6 is a schematic diagram of a voltage timing corresponding to each element at different stages of a program cycle according to an example of the present disclosure;

FIG. 7 is a schematic diagram of a connection between elements in a memory according to an example of the present disclosure;

FIG. 8 is a schematic diagram of a word line voltage timing in different program cycles during a program operation according to an example of the present disclosure;

FIG. 9 is a schematic diagram I of a word line voltage in different program cycles during the program operation according to an example of the present disclosure;

FIG. 10 is a schematic diagram II of a word line voltage in different program cycles during the program operation according to an example of the present disclosure; and

FIG. 11 is an implementation flow diagram of an operation method of a memory device according to an example of the present disclosure.

### DETAILED DESCRIPTION

The technical solutions in implementations of the present disclosure will be described below clearly and completely in conjunction with the implementations and the drawings of the present disclosure. Apparently, the described implementations are merely part, but not all, of the implementations of the present disclosure. All other implementations obtained by those of ordinary skills in the art based on the implementations in the present disclosure without creative work shall fall within the scope of protection of the present disclosure.

In the description below, many particular details are presented to provide a more thorough understanding of the present disclosure. However, it is obvious to a person skilled in the art that the present disclosure may be implemented without one or more of these details. In other examples, in order to avoid confusing with the present disclosure, some technical features well-known in the art are not described; that is, not all features of actual examples are described herein, and well-known functions and structures are not described in detail.

In the drawings, dimensions and relative dimensions of layers, areas, and elements may be exaggerated for clarity. Like reference numerals denote like elements throughout.

It is to be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, and third, etc., may be used to describe various elements, components, areas, layers and/or portions, these elements, components, areas, layers and/or portions should not be limited by these terms. These terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. However, when the second element, component, area, layer or portion is discussed, it does not mean that the first element, component, area, layer or portion is necessarily present in the present disclosure.

The spatially relative terms, such as “beneath”, “below”, “lower”, “under”, “above”, “upper”, and the like, may be used herein for ease of description to describe a relationship of one element or feature with respect to other elements or features as illustrated in the figures. It is to be understood that, the spatially relative terms are intended to further encompass different orientations of a device in use or operation in addition to the orientation depicted in the figures. For example, if the device in the drawings is turned over, then an element or a feature described as being “below other elements”, or “under other elements”, or “beneath other elements” will be orientated as being “above” the other elements or features. Therefore, the example terms “below” and “beneath” may comprise both upper and lower orientations. The device may be orientated otherwise (rotated by 90 degrees or in other orientations), and the spatial descriptive terms used herein are interpreted accordingly.

The terms used herein are intended to describe the particular examples only, and are not used as limitations to the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any and all combinations of related items listed.

In order to understand the present disclosure thoroughly, detailed operations and detailed structures will be proposed in the following description to set forth the technical solution of the present disclosure. Detailed descriptions of the examples of the present disclosure are as follows. However, the present disclosure may also have other implementations in addition to these detailed descriptions.

A memory device in examples of the present disclosure includes, but is not limited to, a three-dimensional NAND memory. For ease of understanding, the three-dimensional NAND memory is used as an example for description.

As the requirements for memory devices increase continuously, how to improve program efficiency has become one of the technical problems required to be solved.

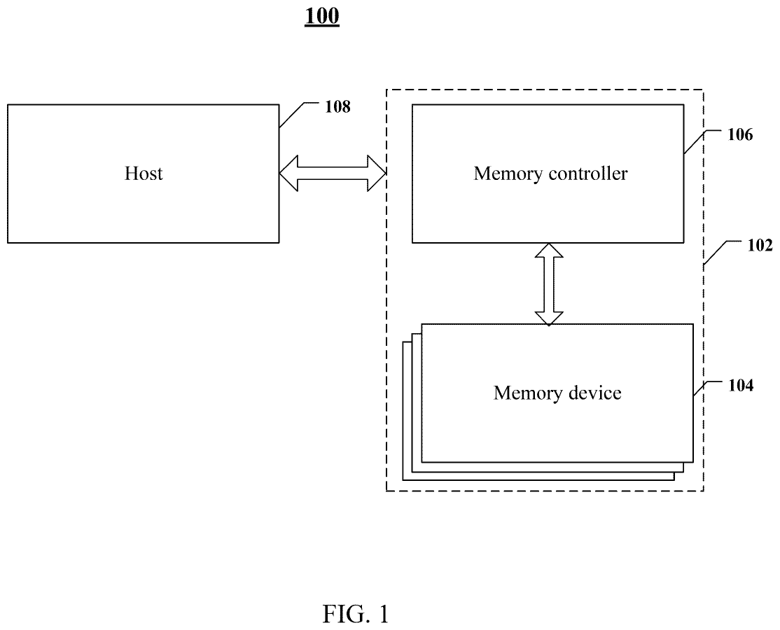

FIG. 1 illustrates a block diagram of an example system 100 having a memory device according to some aspect of the present disclosure. The system 100 may be a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 1, the system 100 may comprise a host 108 and a memory system 102, wherein the memory system 102 has one or more memory devices 104 and a memory controller 106. The host 108 may be a processor (e.g., a central processing unit (CPU)) or a system on chip (SOC) (e.g., an application processor (AP)) of an electronic apparatus. The host 108 may be configured to send or receive data to or from the memory device 104.

According to some implementations, the memory controller 106 is coupled to the memory device 104 and the host 108, and configured to control the memory device 104. The memory controller 106 can manage data stored in the memory device 104 and communicate with the host 108. In some implementations, the memory controller 106 is designed for operating in a low duty-cycle environment, such as a Secure Digital (SD) card, a Compact Flash (CF) card, a Universal Serial Bus (USB) flash driver, or other media for use in electronic apparatuses, such as a personal computer, a digital camera, and a mobile phone, etc. In some implementations, the memory controller 106 is designed for operating in a high duty-cycle environment, such as an SSD or embedded Multi-Media Card (eMMC) that is used as a data memory for a mobile apparatus such as a smartphone, a tablet computer, and a laptop computer, etc., and an enterprise memory array.

The memory controller 106 may be configured to control operations of the memory device 104, such as read, erase, and program operations. The memory controller 106 may be further configured to manage various functions with respect to data stored or to be stored in the memory device 104, including, but not limited to, bad-block management, garbage collection, logical-to-physical address conversion, and wear leveling, etc. In some implementations, the memory controller 106 is further configured to process an Error Correction Code (ECC) with respect to data read from or written to the memory device 104. The memory controller 106 may also perform any other suitable functions, e.g., formatting the memory device 104. The memory controller 106 may communicate with an external apparatus (e.g., the host 108) according to a particular communication protocol. For example, the memory controller 106 may communicate with the external apparatus through at least one of various interface protocols, such as a USB protocol, a MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a Firewire protocol, etc.

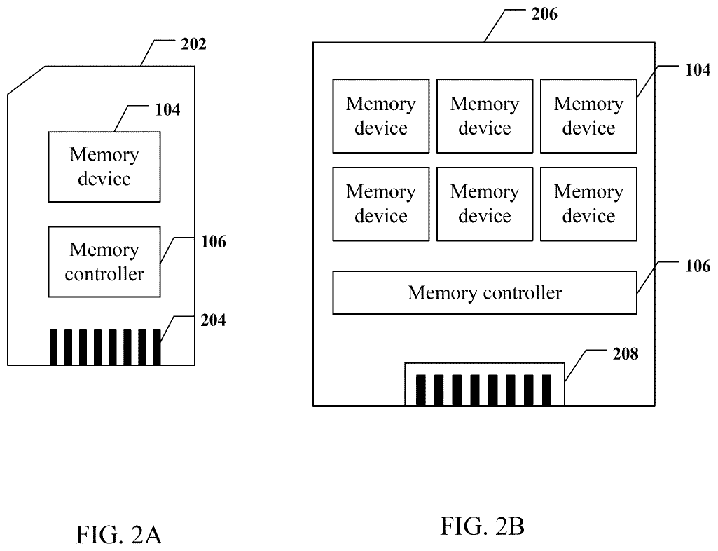

The memory controller 106 and one or more memory devices 104 can be integrated into various types of storage apparatuses, e.g., be included in the same package (such as a Universal Flash Storage (UFS) package or an eMMC package). That is, the memory system 102 can be implemented and packaged into different types of end electronic products. In an example as shown in FIG. 2A, the memory controller 106 and a single memory device 104 may be integrated into a memory card 202. The memory card 202 may include a PC card (Personal Computer Memory Card International Association (PCMCIA)), a CF card, a Smart Media (SM) card, a memory stick, a multimedia card (MMC, RS-MMC, MMCmicro), an SD card (SD, miniSD, microSD, SDHC), and a UFS, etc. The memory card 202 may further comprise a memory card connector 204 coupling the memory card 202 with a host (e.g., the host 108 in FIG. 1). In another example shown in FIG. 2B, the memory controller 106 and the plurality of memory devices 104 may be integrated into an SSD 206. The SSD 206 may further comprise an SSD connector 208 coupling the SSD 206 with a host (e.g., the host 108 in FIG. 1). In some implementations, at least one of a storage capacity or an operation speed of the SSD 206 is greater than that of the memory card 202.

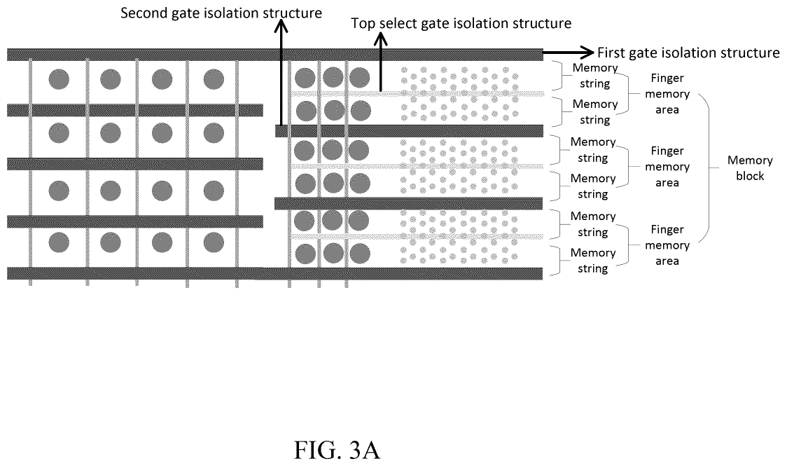

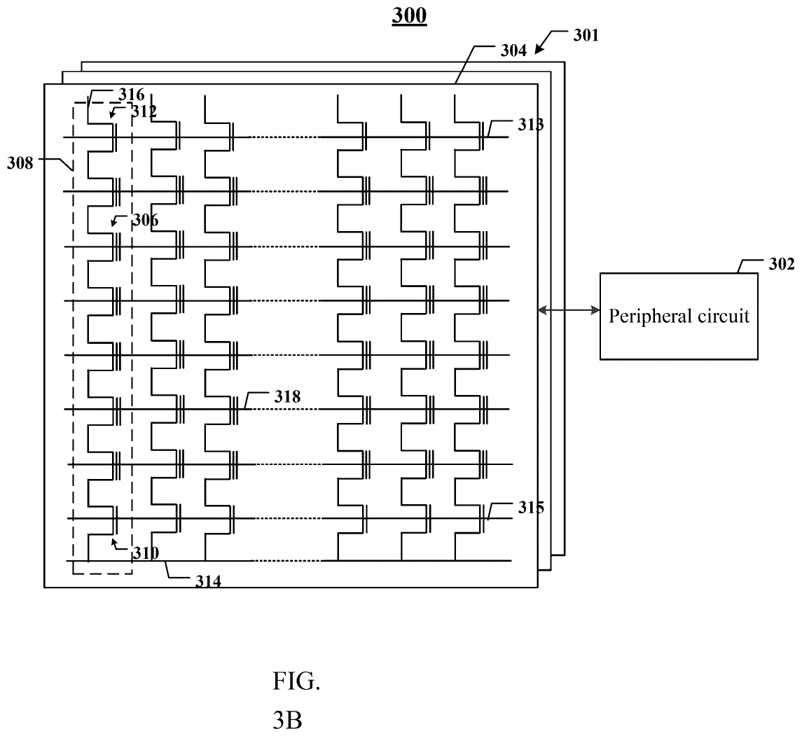

FIG. 3A provides an example of a schematic structural diagram of a memory cell array of a three-dimensional NAND memory. As shown in FIG. 3A, the memory cell array of the three-dimensional NAND memory is composed of a plurality of memory cell rows that are staggered in parallel and parallel to a gate isolation structure. Every two memory cell rows are spaced apart by the gate isolation structure and a top select gate isolation structure, and each memory cell row comprises a plurality of memory cells. The gate isolation structure may comprise first gate isolation structures and second gate isolation structures. The first gate isolation structures divide the memory array into a plurality of memory blocks. A plurality of second gate isolation structures may divide each memory block into a plurality of finger memory areas. The top select gate isolation structure disposed in the middle of each finger memory area may divide the finger memory area into two portions, so as to divide the finger memory area into two memory strings. One memory block shown in FIG. 3A comprises 6 memory strings, and in practical applications, the number of memory strings in one memory block is not limited thereto. Memory cells in one memory block that are coupled with a certain word line may be referred to as one memory page.

It is to be noted that the number of memory cell rows between the gate isolation structure and the top select gate isolation structure shown in FIG. 3A is only an example illustration, which is not used to limit the number of memory cell rows contained in one finger memory area of the three-dimensional NAND memory in the present disclosure. In practical applications, the number of memory cell rows contained in one finger memory area may be adjusted to, for example, 2, 4, 8, and 16, etc., according to practical situations.

FIG. 3B shows a schematic circuit diagram of an example memory device 300 comprising a peripheral circuit according to some aspects of the present disclosure. The memory device 300 may be an example of the memory device 104 in FIG. 1. The memory device 300 may comprise a memory cell array 301 and a peripheral circuit 302 coupled to the memory cell array 301. An illustration is performed with an example in which the memory cell array 301 is a three-dimensional NAND memory cell array, wherein memory cells 306 are provided in an array of NAND memory strings 308, and each NAND memory string 308 extends vertically above a substrate (not shown). In some implementations, each NAND memory string 308 may comprise a plurality of memory cells 306 coupled in series and stacked vertically. Each memory cell 306 may maintain a continuous analog value, such as voltage or charge, which depends on the number of electrons trapped within an area of the memory cell 306. Each memory cell 306 may be a floating gate memory cell that comprises a floating gate transistor, or a charge trap memory cell that comprises a charge trap transistor.

In some implementations, each memory cell 306 is a Single Level Cell (SLC) that has two possible memory states and thus can store one bit of data. For example, a first memory state “0” may correspond to a first voltage range, and a second memory state “1” may correspond to a second voltage range. In some implementations, each memory cell 306 is a Multi Level Cell (MLC) that is capable of storing more than a single bit of data in more than four memory states. For example, the MLC may store two bits per cell, three bits per cell (also referred to as a Triple Level Cell (TLC)), or four bits per cell (also referred to as a Quad Level Cell (QLC)). Each MLC can be programmed to assume a range of possible nominal memory values. In one example, if each MLC stores two bits of data, the MLC can be programmed to assume one of three possible program levels from an erase state by writing one of three possible nominal storage values to the cell. A fourth nominal storage value may be used for the erase state.

As shown in FIG. 3B, each NAND memory string 308 may comprise a bottom select gate (BSG) 310 at its source terminal and a top select gate (TSG) 312 at its drain terminal. The BSG 310 and the TSG 312 may be configured to activate a selected NAND memory string 308 during read and program operations. In some implementations, sources of the NAND memory strings 308 in the same memory block 304 are coupled through the same source line (SL) 314 (e.g., a common SL). In other words, according to some implementations, all the NAND memory strings 308 in the same memory block 304 have an array common source (ACS). According to some implementations, the TSG 312 of each NAND memory string 308 is coupled to a respective bit line (BL) 316, and data may be read from or written into the bit line 316 via an output bus (not shown). In some implementations, each NAND memory string 308 is configured to be selected or unselected by applying a select voltage (e.g., greater than a threshold voltage of a transistor having the TSG 312) or an unselect voltage (e.g., 0 V) to the respective TSG 312 via one or more TSG lines 313 and/or by applying a select voltage (e.g., greater than a threshold voltage of a transistor having the BSG 310) or an unselect voltage (e.g., 0 V) to the respective BSG 310 via one or more BSG lines 315.

As shown in FIG. 3B, the NAND memory strings 308 can be organized into a plurality of memory blocks 304, and each of the plurality of memory block 304 may have a common source line 314 (e.g., coupled to the ground). In some implementations, each memory block 304 is a basic data unit for an erase operation, i.e., all the memory cells 306 on the same memory block 304 are erased at the same time. In order to erase the memory cells 306 in a selected memory block 304a, the source line 314 coupled to the selected memory block 304a and unselected memory blocks 304b that are in the same plane as the selected memory block 304a can be biased with an erase voltage (Vers) (such as a high positive voltage (e.g., 20 V or higher)). It is to be understood that in some examples, the erase operation may be performed at a half memory block level, a quarter memory block level, or a level having any suitable number of memory blocks or any suitable fractions of a memory block. The memory cells 306 of adjacent ones of the NAND memory strings 308 may be coupled through a word line 318, and the word line 318 selects which row of memory cells 306 is affected by the read and program operations.

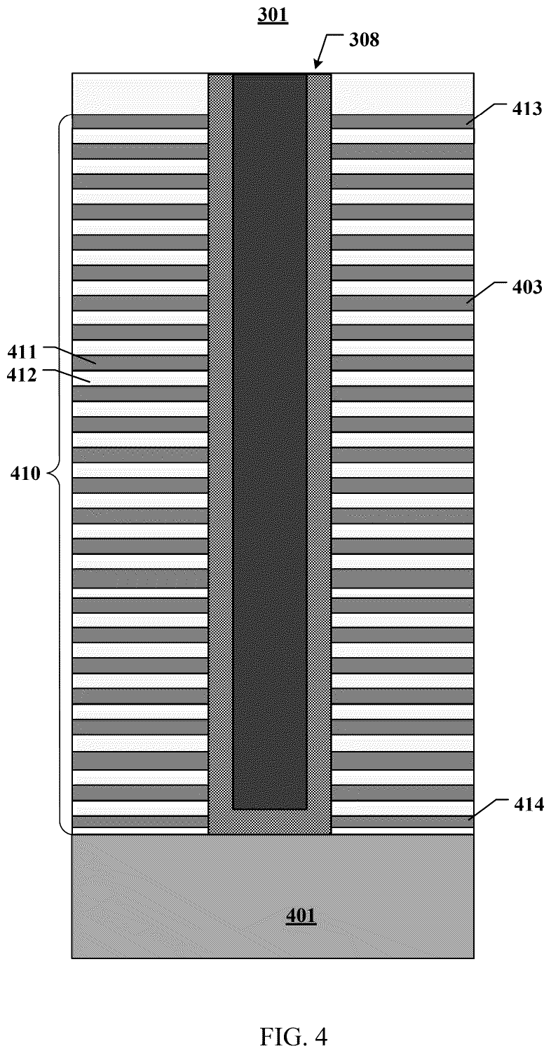

FIG. 4 illustrates a schematic cross-sectional view of the example memory array 301 comprising the NAND memory string 308 according to some aspects of the present disclosure. As shown in FIG. 4, the NAND memory string 308 may comprise a stack structure 410 which comprises a plurality of gate layers 411 and a plurality of insulation layers 412 that are disposed as being stacked sequentially and alternately, and the memory string 308 penetrating through the gate layers 411 and the insulation layers 412 vertically. The gate layers 411 and the insulation layers 412 may be stacked alternately, and two adjacent ones of the gate layers 411 are spaced apart by one insulation layer 412. The number of pairs of the gate layers 411 and the insulation layers 412 in the stack structure 410 may determine the number of memory cells that are included in the memory array 401.

A constituent material of the gate layers 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 comprises a metal layer, e.g., a tungsten layer. In some implementations, each gate layer 411 comprises a doped polysilicon layer. Each gate layer 411 may comprise a control gate surrounding the memory cells. The gate layer 411 at the top of the stack structure 410 may extend laterally as a top select gate line; the gate layer 411 at the bottom of the stack structure 410 may extend laterally as a bottom select gate line; and the gate layer 411 that extends laterally between the top select gate line and the bottom select gate line may serve as a word line layer.

In some examples, the stack structure 410 may be disposed on a substrate 401. The substrate 401 may include silicon (e.g., monocrystalline silicon), silicon germanium (SiGe), gallium arsenide (GaAs), germanium (Ge), silicon on insulator (SOI), germanium on insulator (GOI), or any other suitable materials.

In some examples, the NAND memory string 308 comprises a channel structure that extends through the stack structure 410 vertically. In some implementations, the channel structure comprises a channel hole filled with (one or more types of) semiconductor material (e.g., as a semiconductor channel) and (one or more types of) dielectric material (e.g., as a memory film). In some implementations, the semiconductor channel includes silicon, e.g., polysilicon. In some implementations, the memory film is a composite dielectric layer comprising a tunneling layer, a storage layer (also referred to as a “charge trap/storage layer”), and a barrier layer. The channel structure may have a cylindrical shape (e.g., a pillar shape). According to some implementations, the semiconductor channel, the tunneling layer, the storage layer, and the barrier layer are arranged radially from the center toward the outer surface of the pillar in this order. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high dielectric constant (high-k) dielectric, or any combination thereof. In an example, the memory film may include a composite layer of silicon oxide/silicon oxynitride/silicon oxide (ONO).

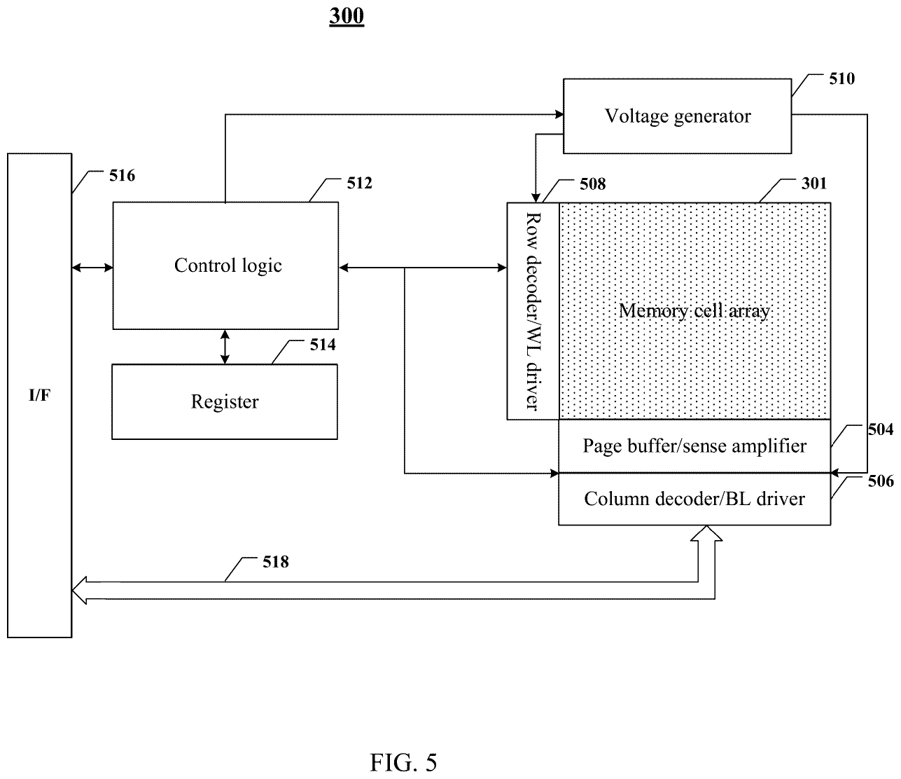

Referring back to FIG. 3B, the peripheral circuit 302 may be coupled to the memory cell array 301 through the bit line 316, the word line 318, the source line 314, the BSG line 315 and the TSG line 313. The peripheral circuit 302 may comprise any suitable analog, digital, and hybrid signal circuits for facilitating operations of the memory cell array 301 by applying at least one of a voltage signal or a current signal to each target memory cell 306 and sensing at least one of a voltage signal or a current signal from each target memory cell 306 via the bit line 316, the word line 318, the source line 314, the BSG line 315, and the TSG line 313. The peripheral circuit 302 may include various types of peripheral circuits formed using a metal-oxide-semiconductor (MOS) technology. For example, FIG. 5 illustrates some example peripheral circuits. The peripheral circuit 302 comprises a page buffer/sense amplifier 504, a column decoder/bit line driver 506, a row decoder/word line driver 508, a voltage generator 510, a control logic 512, a register 514, an interface 516, and a data bus 518. It is to be understood that in some examples, an additional peripheral circuit not shown in FIG. 5 may be included as well.

The page buffer/sense amplifier 504 may be configured to read data from and program (write) data into the memory array 301 according to a control signal from the control logic 512. In one example, the page buffer/sense amplifier 504 may store one page of program data (write data) to be programmed into one page 320 of the memory cell array 301. In another example, the page buffer/sense amplifier 504 may perform a program verification operation to ensure that the data has been properly programmed into the memory cell 306 coupled to the selected word line 318. In still another example, the page buffer/sense amplifier 504 may also sense low power signals from the bit line 316 that represent data bits stored in the memory cells 306, and amplify a small voltage swing to a recognizable logic level during the read operation. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512, select/unselect the memory block 304 of the memory cell array 301, and select/unselect the word line 318 of the memory block 304. The row decoder/word line driver 508 may be further configured to drive the word line 318 using a word line voltage generated from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 that are coupled to (one or more) selected word lines 318. The voltage generator 510 may be configured to be controlled by the control logic 512 and generate the word line voltage (such as a read voltage, a program voltage, a pass voltage, a channel boost voltage, and a verify voltage, etc.), the bit line voltage, and a source line voltage to be supplied to the memory cell array 301.

In some particular examples, the program operation may comprise a plurality of stages. In an example, the program operation may comprise a precharge stage, a channel boost stage, a program pulse stage, and a recovery stage. In the precharge stage, the voltage generator may generate a voltage required in a next stage, such as a voltage used to be applied to gates, and the channel boost voltage. In the channel boost stage, the channel boost voltage may be applied to the selected word line. In the program pulse stage, a target program voltage for each time of programming may be applied to the selected word line. In the recovery stage, voltages on both unselected and selected word lines may be caused to decrease to a lower respective voltage, such as Vcc and Vdd. The purpose of decreasing the voltage to the respective voltage may be achieved through one or more stepped voltage decreases during the recovery stage, for example, the voltage may be decreased to an intermediate voltage first and held at this intermediate voltage for a period of time, and then decreased to the respective voltage.

The control logic 512 may be coupled to each peripheral circuit as described above and configured to control operations of each peripheral circuit. The register 514 may be coupled to the control logic 512 and comprise a state register, a command register, and an address register for storing state information, a command operation code (OP code), and a command address for controlling the operations of each peripheral circuit. The interface 516 may be coupled to the control logic 512, and act as a control buffer to buffer and relay control commands received from a host (not shown) to the control logic 512 and buffer and relay state information received from the control logic 512 to the host. The interface 516 may also be coupled to the column decoder/bit line driver 506 via the data bus 518 and act as a data I/O interface and a data buffer to buffer and relay the data to and from the memory array 301.

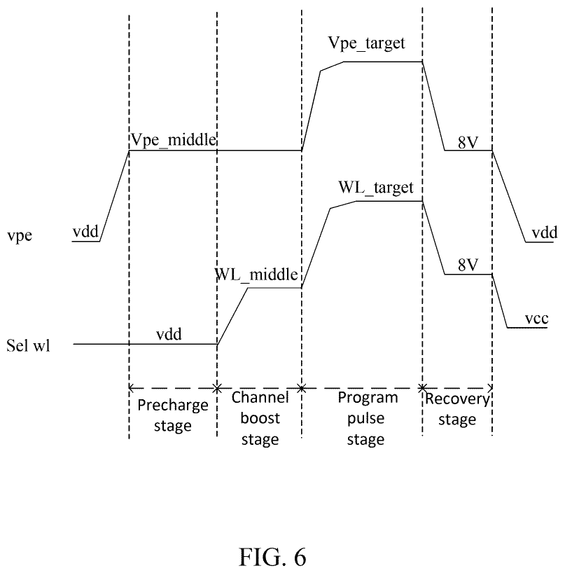

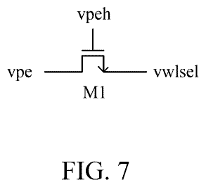

FIG. 6 is a schematic diagram of a voltage timing corresponding to each element at different stages of a program cycle according to an example of the present disclosure. FIG. 7 is a schematic diagram of a connection between elements in a memory according to an example of the present disclosure.

As shown in FIG. 6, during the channel boost stage, a voltage of the selected word line (Sel wl) will rise to a channel boost voltage (WL_middle), e.g., 6.5 V. During the program pulse stage, a voltage of the selected word line will rise to a target program voltage (WL_target). Moreover, the selected word line is connected to a first voltage generator (vpe), so that a voltage rise of the first voltage generator guides the voltage of the selected word line to rise to the target program voltage. A boost voltage (Vpe_middle) of the first voltage generator is the same as or differs slightly from the channel boost voltage (WL_middle), and a target voltage (Vpe_target) of the first voltage generator is the same as or differs slightly from the target program voltage (WL_target). Here, the first voltage generator is coupled with the selected word line, and a voltage relationship therebetween may be understood as follows: the boost voltage (Vpe_middle) is the same as or differs slightly from the channel boost voltage (WL_middle), and the target voltage (Vpe_target) is the same as or differs slightly from the target program voltage (WL_target). The slight difference may be caused by an actual circuit environment, such as a loss in a connection line coupling the first voltage generator and the selected word line.

It may be understood that in the above example, from the channel boost stage to the program pulse stage, as can be seen from FIG. 7, when a first transistor M1 is on, a voltage (vwlsel) generated by the first voltage generator (vpe) is connected to the selected word line, and a voltage switch occurs at an end of the first transistor M1 that is connected with the selected word line. The selected word line (Sel wl) is connected with the first voltage generator (vpe). At the instant of turning on the first transistor M1, a large Drain Source Voltage (VDS) between vpe and Sel wl causes degradation of the performance of the first transistor M1, ultimately leading to degradation of the performance of the device. A small drain source voltage between vpe and Sel wl results in a small Hot Carrier Injection (HCI) when the first transistor M1 is on. However, at this time, when the voltage of vpe rises, Sel wl is loaded onto vpe, causing the voltage of vpe to rise slowly. A slow voltage rise of vpe causes a voltage rise of Sel wl to be slower than that is expected, i.e., affecting a voltage rise speed of the selected word line, thereby affecting final program time (tProg).

Based on one or more of the above problems, examples of the present disclosure provide another memory device, comprising: a memory cell array; and a peripheral circuit coupled to the memory cell array and configured to: determine a target voltage difference according to a target program voltage; determine a channel boost voltage according to a difference between the target program voltage and the target voltage difference; apply the channel boost voltage to a selected word line during a channel boost stage; and apply the target program voltage to the selected word line during a program pulse stage.

In some examples, the target voltage difference is a difference between the target program voltage and the channel boost voltage. The channel boost voltage may be obtained by subtracting the target voltage difference from the target program voltage.

Here, the selected word line may be any one of a plurality of word lines in the memory cell array. The target program voltage may be generated by the first voltage generator. The first voltage generator is subordinate to the voltage generator 510 mentioned above, and the first voltage generator is configured to generate the channel boost voltage and the target program voltage used to be applied to the selected word line.

It may be understood that in the examples of the present disclosure, Incremental Step-Pulse Programming (ISPP) may be used to perform a program operation on the memory device. In an implementation, during the program operation of a target state, a first target program voltage is applied to the selected word line first, and then a verification operation is performed on target memory cells connected to the selected word line, so as to check whether a threshold voltage of each target memory cell connected to the selected word line reaches a target threshold voltage. If the number of target memory cells that have not been programmed to the target threshold voltage is greater than a tolerance range, a higher second target program voltage is applied, and a verification operation is performed again after the second target program voltage is applied. The above process of applying a program pulse and performing the verification operation is repeated, and the program does not end until the number of target memory cells that have not been programmed to the target threshold voltage is within the tolerance range.

It is to be noted that the voltage generated by the first voltage generator (vpe) rises to the channel boost voltage before applying the channel boost voltage to the selected word line, and the voltage generated by the first voltage generator rises from the channel boost voltage to the target program voltage before applying the target program voltage to the selected word line. Still referring to above FIG. 6, during the channel boost stage, the channel boost voltage is applied to the selected word line, so that the voltage on the selected word line rises from a ground voltage Vad (0 V) to the channel boost voltage; during the program pulse stage, the target program voltage is applied to the selected word line, so that the voltage on the selected word line rises from the channel boost voltage to the target program voltage with a certain slope.

In the examples of the present disclosure, during application of a program voltage, an intermediate voltage, i.e., the channel boost voltage, is applied to the selected word line first, and then the target program voltage is applied to the selected word line, so that the voltage on the selected word line rises from the channel boost voltage to the target program voltage. Voltage buffering may be realized effectively, thereby reducing the damage to the first transistor caused by a large voltage difference due to the one-time rise from the ground voltage to the target program voltage.

In the examples of the present disclosure, the target voltage difference is determined according to the target program voltage; and the channel boost voltage is determined according to the difference between the target program voltage and the target voltage difference. That is, the target voltage difference in the examples of the present disclosure varies as the target program voltage varies, so as to control the target voltage difference within a certain range, so that damage to the first transistor due to a large voltage difference as well as long program time (tProg) due to a small voltage difference is avoided.

In the examples of the present disclosure, the peripheral circuit comprises a control logic and a first voltage generator coupled with the control logic; the control logic is configured to: control the first voltage generator to generate the channel boost voltage, and apply the channel boost voltage to the selected word line; and control the first voltage generator to generate the target program voltage, and apply the target program voltage to the selected word line.

In the examples of the present disclosure, the peripheral circuit further comprises a row driver, and the first voltage generator is coupled with the selected word line through a first transistor in the row driver; the control logic is configured to: during the channel boost stage, turn on the first transistor, so as to output the channel boost voltage generated by the first voltage generator to the selected word line; and during the program pulse stage, turn on the first transistor, so as to output the target program voltage generated by the first voltage generator to the selected word line.

Here, the control logic may be understood with reference to the control logic 512 in above FIG. 5. After receiving a program operation (write) command, the control logic may start responding to the program operation command to execute the program operation, during execution of the program operation, controls the first voltage generator to generate the channel boost voltage and applies the channel boost voltage to the selected word line, and controls the first voltage generator to generate the target program voltage and applies the target program voltage to the selected word line.

In the examples of the present disclosure, the peripheral circuit further comprises a second voltage generator coupled with the control logic; the control logic is configured to: control a voltage generated by the second voltage generator to rise to a first voltage, and during the program pulse stage, apply the first voltage to a gate of the first transistor, so as to turn on the first transistor.

Here, in an implementation, the row driver may be the WL driver 508 in above FIG. 5; the second voltage generator is also subordinate to the voltage generator 510 in above FIG. 5, and the second voltage generator is configured to generate a gate voltage used to be applied to a gate of the first transistor. The second voltage generator may correspond to vpeh in FIG. 7.

Here, the value of the first voltage is related to the type of the first transistor. In some particular examples, the first transistor is an N-Metal-Oxide-Semiconductor (NMOS) transistor, wherein the first voltage is greater than the target program voltage and the voltage difference between the first voltage and the target program voltage is required to be greater than a turning-on voltage of the first transistor, so that the first transistor may be turned on.

In the examples of the present disclosure, a magnitude of the target voltage difference is positively correlated with a magnitude of the target program voltage.

In the examples of the present disclosure, the target voltage difference increases as the target program voltage increase. As such, when the target program voltage is small, a small target voltage difference is used; when the target program voltage is large, a relatively large target voltage difference is used, so as to improve the voltage rise speed of the selected word line as much as possible while ensuring that no damage is caused to the first transistor M1, thereby achieving the purpose of saving the program time (tProg).

In the examples of the present disclosure, the target voltage difference presents an incremental trend during programming of a selected memory cell.

In the examples of the present disclosure, programming is performed using the ISPP method, in which the target program voltage presents an incremental trend during the programming of selected memory cells, so that the target voltage difference also presents an incremental trend.

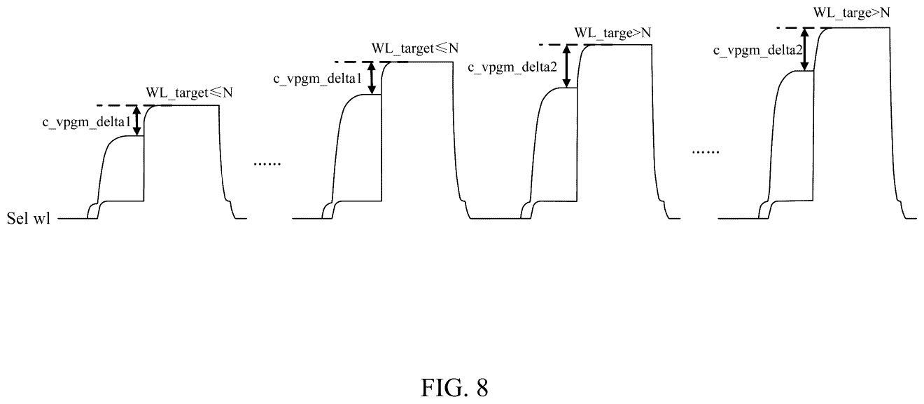

FIG. 8 is a schematic diagram of a word line voltage timing in different program cycles during a program operation according to an example of the present disclosure. As shown in FIG. 8, at an initial stage of the program operation, the target program voltage (WL_target) is less than or equal to a preset value, i.e., WL_target_N. At this time, since the target program voltage is small, c_vpgm_delta1 is used as the target voltage difference, so that a voltage difference caused by a rise from the ground voltage to the channel boost voltage and a voltage difference caused by a rise from the channel boost voltage to the target program voltage are both small, causing no damage to the first transistor. At middle and later stages of the program operation, the target program voltage is greater than the preset value, i.e., WL_target>N. At this time, since the target program voltage is large, if c_vpgm_delta1 continues to be used as the target voltage difference, a voltage difference caused by a rise from the ground voltage to the channel boost voltage may become large enough to cause a degrading effect on the first transistor. Therefore, at this time, c_vpgm_delta2 is used as the target voltage difference, and c_vpgm_delta2 is greater than c_vpgm_delta1, thereby reducing the voltage difference caused by the rise from the ground voltage to the channel boost voltage and avoiding damage to the first transistor due to the large voltage difference.

In the examples of the present disclosure, the peripheral circuit is configured to: compare the target program voltage with a preset value; and determine the target voltage difference according to a comparison result.

In the examples of the present disclosure, in order to adjust the value of the target voltage difference according to the magnitude of the target program voltage, the target program voltage is compared with the preset value, whereby the target voltage difference may be determined according to the comparison result of the target program voltage and the preset value.

In the examples of the present disclosure, the peripheral circuit is configured to: when the target program voltage is less than or equal to the preset value, determine the target voltage difference to be a first target voltage difference; and when the target program voltage is greater than the preset value, determine the target voltage difference to be a second target voltage difference, wherein the first target voltage difference is less than the second target voltage difference.

In a particular example, the preset value may be set to 20, 22, 24, or 26.

It may be understood that in the examples of the present disclosure, the program operation may be divided into a plurality of program cycles according to different target program voltages, a respective target program voltage is applied to the selected word line in each program cycle, and each program cycle corresponds to an individual program pulse. Each program cycle comprises the precharge stage, the channel boost stage, the program pulse stage, and the recovery stage as mentioned above. That is, the above solution, which involves determining the target voltage difference according to the target program voltage, determining the channel boost voltage according to the difference between the target program voltage and the target voltage difference, applying the channel boost voltage to the selected word line during the channel boost stage, and applying the target program voltage to the selected word line during the program pulse stage, may be applied to each program cycle.

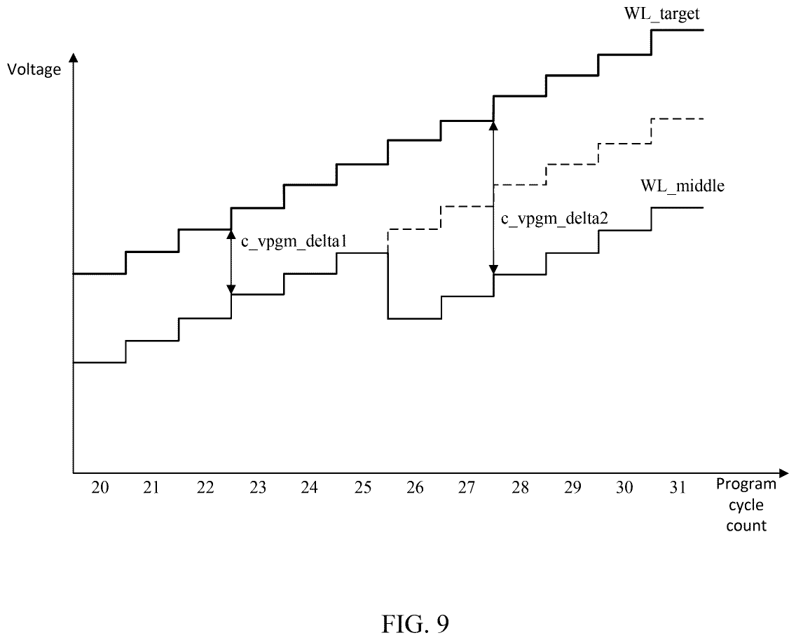

FIG. 9 is a schematic diagram I of a word line voltage in different program cycles during the program operation according to an example of the present disclosure. As shown in FIG. 9, when the target program voltage (WL_target) is less than or equal to the preset value, the target voltage difference is c_vpgm_delta1, i.e., the difference between the target program voltage (WL_target) and the channel boost voltage (WL_middle) is c_vpgm_delta1. For example, in early 25 program cycles, target program voltages are all less than or equal to the preset value. Accordingly, c_vpgm_delta1 is used as the target voltage difference in the 1st to 25th program cycles. When the target program voltage is greater than the preset value, the target voltage difference becomes c_vpgm_delta2, i.e., the difference between the target program voltage (WL_target) and the channel boost voltage (WL_middle) is c_vpgm_delta1. For example, target program voltages in program cycles following the 25th program cycle are all greater than the preset value. Accordingly, c_vpgm_delta2 is used as the target voltage difference in the 26th to the last program cycles. c_vpgm_delta2 is greater than c_vpgm_delta1. It is to be noted that the dashed line in FIG. 9 is a voltage curve in the case where the difference between the target program voltage (WL_target) and the channel boost voltage (WL_middle) is constantly c_vpgm_delta1, in which case the target program voltage (WL_target) becomes increasingly large as the program cycles advance, and if c_vpgm_delta1 continues to be used as the target voltage difference, the voltage difference caused by a rise from the ground voltage to the channel boost voltage may become large enough to cause a degrading effect on the first transistor, which ultimately leads to the degradation of the device performance. However, in the device provided in the present application, the target voltage difference is determined according to the target program voltage, wherein c_vpgm_delta2 is used as the target voltage difference when the target program voltage is greater than the preset value, and c_vpgm_delta2 is greater than c_vpgm_delta1, thereby reducing the voltage difference caused by the rise from the ground voltage to the channel boost voltage and avoiding damage to the first transistor due to the large voltage difference.

In the examples of the present disclosure, when the target program voltage is less than or equal to a first preset value, the target voltage difference is determined to be a first target voltage difference; when the target program voltage is greater than the first preset value and less than or equal to a second preset value, the target voltage difference is determined to be a second target voltage difference; and when the target program voltage is greater than the second preset value, the target voltage difference is determined to be a third target voltage difference, wherein the first target voltage difference is less than the second target voltage difference, the second target voltage difference is less than the third target voltage difference, and the first preset value is less than the second preset value.

In a particular example, the first preset value may be set to 18, 19, 20, or 21. The second preset value may be set to 22, 23, 24, or 25.

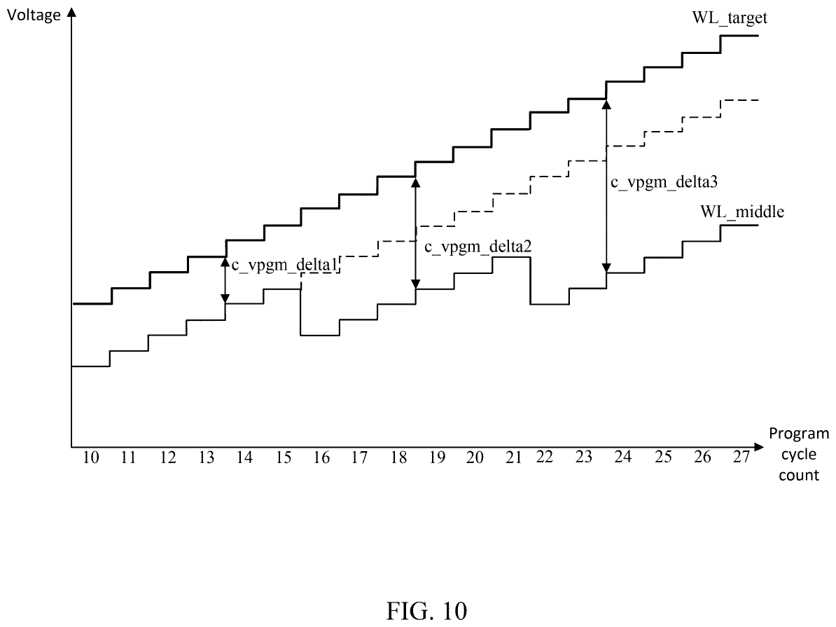

FIG. 10 is a schematic diagram II of a word line voltage in different program cycles during the program operation according to an example of the present disclosure. As shown in FIG. 10, when the target program voltage (WL_target) is less than or equal to the first preset value, the target voltage difference is c_vpgm_delta1, i.e., the difference between the target program voltage (WL_target) and the channel boost voltage (WL_middle) is c_vpgm_delta1. For example, in early 15 program cycles, target program voltages are all less than or equal to the first preset value. Accordingly, c_vpgm_delta1 is used as the target voltage difference in the 1st to 15th program cycles. When the target program voltage is greater than the first preset value and less than or equal to the second preset value, the target voltage difference becomes c_vpgm_delta2, i.e., the difference between the target program voltage (WL_target) and the channel boost voltage (WL_middle) is c_vpgm_delta2. For example, target program voltages in the 16th to the 21st program cycles are all greater than the preset value. Accordingly, c_vpgm_delta2 is used as the target voltage difference in the 16th to the 21st program cycles. When the target program voltage is greater than the second preset value, the target voltage difference becomes c_vpgm_delta3, i.e., the difference between the target program voltage (WL_target) and the channel boost voltage (WL_middle) is c_vpgm_delta3. For example, target program voltages in program cycles following the 21st program cycle are all greater than the preset value. Accordingly, c_vpgm_delta3 is used as the target voltage difference in the 22nd to the last program cycles. c_vpgm_delta2 is greater than c_vpgm_delta1, and c_vpgm_delta3 is greater than c_vpgm_delta2. It is to be noted that the dashed line in FIG. 10 is a voltage curve in the case where the difference between the target program voltage (WL_target) and the channel boost voltage (WL_middle) is constantly c_vpgm_delta1, in which case the target program voltage (WL_target) becomes increasingly large as the program cycles advance, and if c_vpgm_delta1 continues to be used as the target voltage difference, the voltage difference caused by a rise from the ground voltage to the channel boost voltage may become large enough to cause a degrading effect on the first transistor, which ultimately leads to the degradation of the device performance. However, in the device provided in the present application, the target voltage difference is determined according to the target program voltage, wherein c_vpgm_delta2 is used as the target voltage difference when the target program voltage is greater than the first preset value and less than or equal to the second preset value, c_vpgm_delta3 is used as the target voltage difference when the target program voltage is greater than the second preset value, c_vpgm_delta3 is greater than c_vpgm_delta2, and c_vpgm_delta2 is greater than c_vpgm_delta1, thereby reducing the voltage difference caused by the rise from the ground voltage to the channel boost voltage and avoiding damage to the first transistor due to the large voltage difference.

In some examples, the memory device comprises a three-dimensional NAND memory.

However, the memory device in the examples of the present disclosure is not limited to the three-dimensional NAND memory. In the examples of the present disclosure, the memory device may be a semiconductor memory, including, but not limited to, a three-dimensional NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), or a Nano Random Access Memory (NRAM), etc.

Examples of the present disclosure further provide a memory system. The memory system comprises:
one or more memory devices as described in any one of the above examples; and
a memory controller coupled to the memory device and configured to control the memory device.

Here, particular structures and compositions with respect to the memory system may be referred to related structures and compositions of the memory system 102 in FIG. 1, FIG. 2A, and FIG. 2B. For simplicity, details are no longer repeated here.

In some examples, the memory system comprises a memory card or a solid state drive.

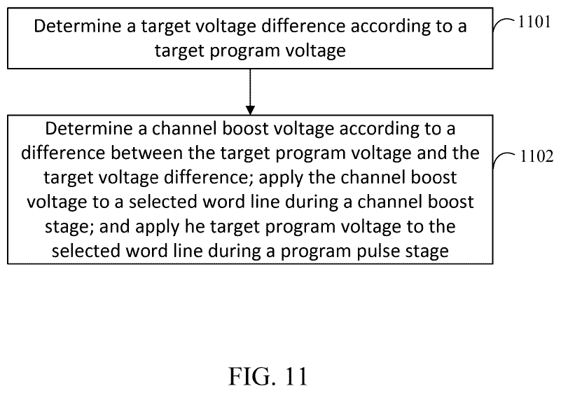

Based on the memory device mentioned above, examples of the present disclosure further provide an operation method of a memory device. As shown in FIG. 11, the method comprises:
S1101: determining a target voltage difference according to a target program voltage; and
S1102: determining a channel boost voltage according to a difference between the target program voltage and the target voltage difference; applying the channel boost voltage to a selected word line during a channel boost stage; and applying the target program voltage to the selected word line during a program pulse stage.

In some examples, a magnitude of the target voltage difference is positively correlated with a magnitude of the target program voltage.

In some examples, the target voltage difference presents an incremental trend during programming of a selected memory cell.

In some examples, the determining the target voltage difference according to the target program voltage comprises: comparing the target program voltage with a preset value; and determining the target voltage difference according to a comparison result.

In some examples, the determining the target voltage difference according to the comparison result comprises: when the target program voltage is less than or equal to the preset value, determining the target voltage difference to be a first target voltage difference; and when the target program voltage is greater than the preset value, determining the target voltage difference to be a second target voltage difference, wherein the first target voltage difference is less than the second target voltage difference.

In some examples, the determining the target voltage difference according to the comparison result comprises: when the target program voltage is less than or equal to a first preset value, determining the target voltage difference to be a first target voltage difference; when the target program voltage is greater than the first preset value and less than or equal to a second preset value, determining the target voltage difference to be a second target voltage difference; and when the target program voltage is greater than the second preset value, determining the target voltage difference to be a third target voltage difference, wherein the second target voltage difference is less than the third target voltage difference, and the first preset value is less than the second preset value.

It is to be understood that “one example” and “an example” mentioned in the whole specification mean that specific features, structures or characteristics related to the example are included in at least one example of the present disclosure. Therefore, “in one example” or “in an example” appearing at any place throughout specification does not always refer to the same example. In addition, these specific features, structures or characteristics may be combined in one or more examples in any proper manner. It is to be understood that, in various examples of the present disclosure, the sequence number of each process does not mean the sequence of execution. The execution sequence of each process should be determined by its functions and internal logic, which should not constitute any limitation on the implementation process of the examples of the present disclosure. The above sequence numbers of the examples of the present disclosure are only for description, and do not represent goodness and badness of the examples.

Examples of the present disclosure provide a memory device and an operation method thereof, and a memory system.

In a first aspect, examples of the present disclosure provide a memory device, comprising: a memory cell array; and a peripheral circuit coupled to the memory cell array and configured to: determine a target voltage difference according to a target program voltage; determine a channel boost voltage according to a difference between the target program voltage and the target voltage difference; apply the channel boost voltage to a selected word line during a channel boost stage; and apply the target program voltage to the selected word line during a program pulse stage.

In an example implementation, a magnitude of the target voltage difference is positively correlated with a magnitude of the target program voltage.

In an example implementation, the target voltage difference presents an incremental trend during programming of a selected memory cell.

In an example implementation, the peripheral circuit is configured to: compare the target program voltage with a preset value; and determine the target voltage difference according to a comparison result.

In an example implementation, the peripheral circuit is configured to: when the target program voltage is less than or equal to the preset value, determine the target voltage difference to be a first target voltage difference; and when the target program voltage is greater than the preset value, determine the target voltage difference to be a second target voltage difference, wherein the first target voltage difference is less than the second target voltage difference.

In an example implementation, the peripheral circuit is configured to: when the target program voltage is less than or equal to a first preset value, determine the target voltage difference to be a first target voltage difference; when the target program voltage is greater than the first preset value and less than or equal to a second preset value, determine the target voltage difference to be a second target voltage difference; and when the target program voltage is greater than the second preset value, determine the target voltage difference to be a third target voltage difference, wherein the first target voltage difference is less than the second target voltage difference, the second target voltage difference is less than the third target voltage difference, and the first preset value is less than the second preset value.

In an example implementation, the peripheral circuit comprises a control logic and a first voltage generator coupled with the control logic; the control logic is configured to: control the first voltage generator to generate the channel boost voltage, and apply the channel boost voltage to the selected word line; and control the first voltage generator to generate the target program voltage, and apply the target program voltage to the selected word line.

In an example implementation, the peripheral circuit further comprises a row driver, and the first voltage generator is coupled with the selected word line through a first transistor in the row driver; the control logic is configured to: during the channel boost stage, turn on the first transistor, so as to output the channel boost voltage generated by the first voltage generator to the selected word line; and during the program pulse stage, turn on the first transistor, so as to output the target program voltage generated by the first voltage generator to the selected word line.

In an example implementation, the peripheral circuit further comprises a second voltage generator coupled with the control logic; the control logic is configured to: control a voltage generated by the second voltage generator to rise to a first voltage, and during the program pulse stage, apply the first voltage to a gate of the first transistor, so as to turn on the first transistor.

In a second aspect, examples of the present disclosure provide a memory system, comprising: the memory device as described in any example of the first aspect; and a memory controller coupled to the memory device and configured to control the memory device.

In a third aspect, examples of the present disclosure provide an operation method of a memory device, comprising: determining a target voltage difference according to a target program voltage; determining a channel boost voltage according to a difference between the target program voltage and the target voltage difference; applying the channel boost voltage to a selected word line during a channel boost stage; and applying the target program voltage to the selected word line during a program pulse stage.

In an example implementation, a magnitude of the target voltage difference is positively correlated with a magnitude of the target program voltage.

In an example implementation, the target voltage difference presents an incremental trend during programming of a selected memory cell.

In an example implementation, the determining the target voltage difference according to the target program voltage comprises: comparing the target program voltage with a preset value; and determining the target voltage difference according to a comparison result.

In an example implementation, the determining the target voltage difference according to the comparison result comprises: when the target program voltage is less than or equal to the preset value, determining the target voltage difference to be a first target voltage difference; and when the target program voltage is greater than the preset value, determining the target voltage difference to be a second target voltage difference, wherein the first target voltage difference is less than the second target voltage difference.

In an example implementation, the determining the target voltage difference according to the comparison result comprises: when the target program voltage is less than or equal to a first preset value, determining the target voltage difference to be a first target voltage difference; when the target program voltage is greater than the first preset value and less than or equal to a second preset value, determining the target voltage difference to be a second target voltage difference; and when the target program voltage is greater than the second preset value, determining the target voltage difference to be a third target voltage difference, wherein the second target voltage difference is less than the third target voltage difference, and the first preset value is less than the second preset value.

Examples of the present disclosure provide a memory device and an operation method thereof, and a memory system. The memory device comprises: a memory cell array; and a peripheral circuit coupled to the memory cell array and configured to: determine a target voltage difference according to a target program voltage; determine a channel boost voltage according to a difference between the target program voltage and the target voltage difference; apply the channel boost voltage to a selected word line during a channel boost stage; and apply the target program voltage to the selected word line during a program pulse stage. In the examples of the present disclosure, the target voltage difference is determined according to the target program voltage; and the channel boost voltage is determined according to the difference between the target program voltage and the target voltage difference. That is, the target voltage difference in the examples of the present disclosure varies as the target program voltage varies, so as to control the target voltage difference within a certain range, so that damage to the first transistor M1 due to a large voltage difference as well as long program time (tProg) due to a small voltage difference is avoided. The above descriptions are merely preferred implementations of the present disclosure, and not intended to limit the scope of the present disclosure. Equivalent structure transformation made within using the contents of the specification and the drawings of the present disclosure under the inventive concept of the present disclosure, or direct/indirect application to other related technical fields are both encompassed within the protection scope of the present disclosure.

What is claimed is:

1. A memory device, comprising:
a memory cell array; and
a peripheral circuit coupled to the memory cell array and configured to:
determine a target voltage difference according to a target program voltage;
determine a channel boost voltage according to a difference between the target program voltage and the target voltage difference;
apply the channel boost voltage to a selected word line during a channel boost stage; and
apply the target program voltage to the selected word line during a program pulse stage.

2. The memory device of claim 1, wherein a magnitude of the target voltage difference is positively correlated with a magnitude of the target program voltage.

3. The memory device of claim 1, wherein the target voltage difference presents an incremental trend during programming of a selected memory cell.

4. The memory device of claim 1, wherein the peripheral circuit is configured to:
compare the target program voltage with a preset value; and
determine the target voltage difference according to a comparison result.

5. The memory device of claim 4, wherein the peripheral circuit is configured to:
when the target program voltage is less than or equal to the preset value, determine the target voltage difference to be a first target voltage difference; and
when the target program voltage is greater than the preset value, determine the target voltage difference to be a second target voltage difference,
wherein the first target voltage difference is less than the second target voltage difference.

6. The memory device of claim 4, wherein the peripheral circuit is configured to:
when the target program voltage is less than or equal to a first preset value, determine the target voltage difference to be a first target voltage difference;
when the target program voltage is greater than the first preset value and less than or equal to a second preset value, determine the target voltage difference to be a second target voltage difference; and
when the target program voltage is greater than the second preset value, determine the target voltage difference to be a third target voltage difference,
wherein the first target voltage difference is less than the second target voltage difference, the second target voltage difference is less than the third target voltage difference, and the first preset value is less than the second preset value.

7. The memory device of claim 1, wherein the peripheral circuit includes:
a first voltage generator coupled with a control logic; and
the control logic configured to:
control the first voltage generator to generate the channel boost voltage, and apply the channel boost voltage to the selected word line; and
control the first voltage generator to generate the target program voltage, and apply the target program voltage to the selected word line.

8. The memory device of claim 7, wherein the peripheral circuit further includes a row driver, and the first voltage generator is coupled with the selected word line through a first transistor in the row driver, wherein the control logic is configured to:
during the channel boost stage, turn on the first transistor, so as to output the channel boost voltage generated by the first voltage generator to the selected word line; and
during the program pulse stage, turn on the first transistor, so as to output the target program voltage generated by the first voltage generator to the selected word line.

9. The memory device of claim 8, wherein the peripheral circuit further includes a second voltage generator coupled with the control logic, wherein the control logic is configured to:
control a voltage generated by the second voltage generator to rise to a first voltage, and
during the program pulse stage, apply the first voltage to a gate of the first transistor so as to turn on the first transistor.

10. A memory system, comprising:
a memory device, including:
a memory cell array; and
a peripheral circuit coupled to the memory cell array and configured to:
determine a target voltage difference according to a target program voltage;
determine a channel boost voltage according to a difference between the target program voltage and the target voltage difference;
apply the channel boost voltage to a selected word line during a channel boost stage; and
apply the target program voltage to the selected word line during a program pulse stage; and
a memory controller coupled to the memory device and configured to control the memory device.

11. The memory system of claim 10, wherein a magnitude of the target voltage difference is positively correlated with a magnitude of the target program voltage.

12. The memory system of claim 10, wherein the target voltage difference presents an incremental trend during programming of a selected memory cell.

13. The memory system of claim 10, wherein the peripheral circuit is configured to:
compare the target program voltage with a preset value; and
determine the target voltage difference according to a comparison result.

14. The memory system of claim 13, wherein the peripheral circuit is configured to:
when the target program voltage is less than or equal to the preset value, determine the target voltage difference to be a first target voltage difference; and
when the target program voltage is greater than the preset value, determine the target voltage difference to be a second target voltage difference,
wherein the first target voltage difference is less than the second target voltage difference.

15. An operation method of a memory device, the operation method comprising:
determining a target voltage difference according to a target program voltage;
determining a channel boost voltage according to a difference between the target program voltage and the target voltage difference;
applying the channel boost voltage to a selected word line during a channel boost stage; and
applying the target program voltage to the selected word line during a program pulse stage.

16. The operation method of a memory device of claim 15, wherein a magnitude of the target voltage difference is positively correlated with a magnitude of the target program voltage.

17. The operation method of a memory device of claim 15, wherein the target voltage difference presents an incremental trend during programming of a selected memory cell.

18. The operation method of a memory device of claim 15, wherein the determining the target voltage difference according to the target program voltage includes:
comparing the target program voltage with a preset value; and
determining the target voltage difference according to a comparison result.

19. The operation method of a memory device of claim 18, wherein the determining the target voltage difference according to the comparison result includes:
when the target program voltage is less than or equal to the preset value, determining the target voltage difference to be a first target voltage difference; and
when the target program voltage is greater than the preset value, determining the target voltage difference to be a second target voltage difference,
wherein the first target voltage difference is less than the second target voltage difference.

20. The operation method of a memory device of claim 19, wherein the determining the target voltage difference according to the comparison result includes:
when the target program voltage is less than or equal to a first preset value, determining the target voltage difference to be a first target voltage difference;
when the target program voltage is greater than the first preset value and less than or equal to a second preset value, determining the target voltage difference to be a second target voltage difference; and
when the target program voltage is greater than the second preset value, determining the target voltage difference to be a third target voltage difference,
wherein the second target voltage difference is less than the third target voltage difference, and the first preset value is less than the second preset value.
